(19) United States
(12) Patent Application Publication
(10) Pub. No.: US 2025/0338536 A1
(43) Pub. Date: Oct. 30, 2025

(54) HIGH ELECTRON MOBILITY TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Randy L. Yach, Phoenix, AZ (US); Leon Gross, Phoenix, AZ (US)

(73) Assignee: Microchip Technology Incorporated, Chandler, AZ (US)

(21) Appl. No.: 18/942,716

(22) Filed: Nov. 10, 2024

Related U.S. Application Data
(60) Provisional application No. 63/638,744, filed on Apr. 25, 2024.

(51) Int. Cl. H01L 29/778; H01L 29/20; H01L 29/423; H01L 29/66

(52) U.S. Cl. CPC H10D 30/475; H10D 30/015; H10D 62/8503; H10D 64/411

(57) ABSTRACT

A High-Electron-Mobility-Transistor that may include a substrate with a first barrier layer formed over a first buffer layer formed on the substrate. A doped structure formed over a first portion of the first barrier layer. A first insulating layer formed over a second portion of the first barrier layer. A second barrier layer formed over the first insulating layer. A second buffer layer formed over the second barrier layer. A second insulating layer formed over the second buffer layer. A gate electrode formed within a spacer through the second insulating layer, through the second buffer layer, and through the second barrier layer. A drain terminal formed at a first side of the gate electrode and a source terminal formed at a second side of the gate electrode.

### CROSS-REFERENCE TO RELATED APPLICATION

The present application claims priority to U.S. Provisional Patent Application No. 63/638,744, filed on Apr. 25, 2024, the contents of which are hereby incorporated by reference in their entirety.

### TECHNICAL FIELD

The present disclosure relates high electron mobility transistors (HEMTs), and more specifically to high performance HEMTs and methods for manufacturing same to improve the drive current and to reduce the leakage current of the HEMT.

### SUMMARY

According to an aspect of one or more examples, there is provided a High-Electron-Mobility-Transistor that may include a substrate, a first buffer layer formed on the substrate, a first barrier layer formed over the first buffer layer, a doped structure formed over a first portion of the first barrier layer, a first insulating layer formed over a second portion of the first barrier layer and surrounding the doped structure, a second barrier layer formed over the first insulating layer and formed over a first portion of the doped structure, a second buffer layer formed over the second barrier layer, a second insulating layer formed over the second buffer layer, a spacer formed over a second portion of the doped structure through the second insulating layer, through the second buffer layer, and through the second barrier layer, a gate electrode formed within the spacer through the second insulating layer, through the second buffer layer, and through the second barrier layer, the gate electrode connected to the doped structure, a drain terminal formed at a first side of the gate electrode, and a source terminal formed at a second side of the gate electrode. The substrate may comprise gallium nitride, diamond, silicon carbide, sapphire, aluminum nitride or silicon. The first buffer layer may comprise a first III-V compound semiconductor such as gallium nitride. The second buffer layer may comprise a second III-V compound semiconductor such as gallium nitride. The first barrier layer may comprise aluminum gallium nitride. The second barrier layer may comprise aluminum gallium nitride. The doped structure may comprise P-doped gallium nitride. The first insulating layer may comprise polysilicon, silicon dioxide or a mixture of polysilicon and silicon dioxide. The second insulating layer may comprise polysilicon, silicon dioxide or a mixture of polysilicon and silicon dioxide.

According to an aspect of one or more examples, there is provided method for producing a High-Electron-Mobility-Transistor. The method may include providing a substrate, forming a first buffer layer on the substrate, forming a first barrier layer over the first buffer layer, forming a first insulating layer over a first portion of the first barrier layer, forming a doped structure over a second portion of the first barrier layer and surrounded by the first insulating layer, forming a second barrier layer over the first insulating layer and over a portion of the doped structure, forming a second buffer layer over the second barrier layer, forming a second insulating layer over the second buffer layer, forming a spacer over the portion of the doped structure, the spacer going through the second insulating layer, through the second buffer layer, and through the second barrier layer, forming a gate electrode within the spacer through the second insulating layer, through the second buffer layer, and through the second barrier layer, the gate electrode connected to the doped structure, forming a drain terminal at a first side of the gate electrode, and forming a source terminal at a second side of the gate electrode. The substrate may comprise gallium nitride, diamond, silicon carbide, sapphire, aluminum nitride or silicon. The first buffer layer may comprise a first III-V compound semiconductor such as gallium nitride. The second buffer layer may comprise a second III-V compound semiconductor such as gallium nitride. The first barrier layer may comprise aluminum gallium nitride. The second barrier layer may comprise aluminum gallium nitride. The doped structure may comprise P-doped gallium nitride. The first insulating layer may comprise polysilicon, silicon dioxide or a mixture of polysilicon and silicon dioxide. The second insulating layer may comprise polysilicon, silicon dioxide or a mixture of polysilicon and silicon dioxide.

### BRIEF DESCRIPTION OF DRAWINGS

FIG. 1A is a cross sectional view of a High-Electron-Mobility-Transistor according to one or more examples;

FIG. 1B is a top sectional view of a High-Electron-Mobility-Transistor according to one or more examples;

FIG. 2A is cross sectional view of some of the steps in a method of manufacturing a High-Electron-Mobility-Transistor according to one or more examples;

FIG. 2B is cross sectional view of some of the steps in a method of manufacturing a High-Electron-Mobility-Transistor according to one or more examples;

FIG. 2C is cross sectional view of some of the steps in a method of manufacturing a High-Electron-Mobility-Transistor according to one or more examples;

FIG. 2D is cross sectional view of some of the steps in a method of manufacturing a High-Electron-Mobility-Transistor according to one or more examples; and

FIG. 2E is cross sectional view of some of the steps in a method of manufacturing a High-Electron-Mobility-Transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

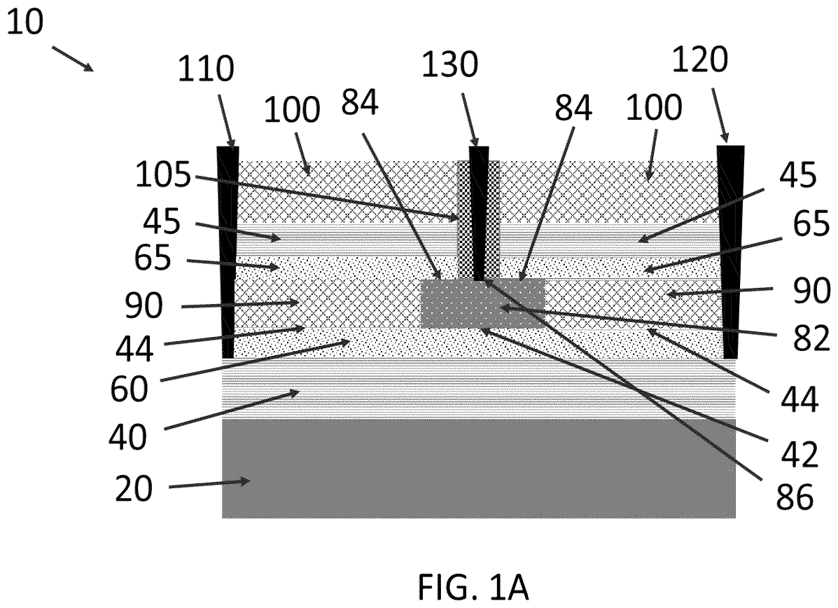

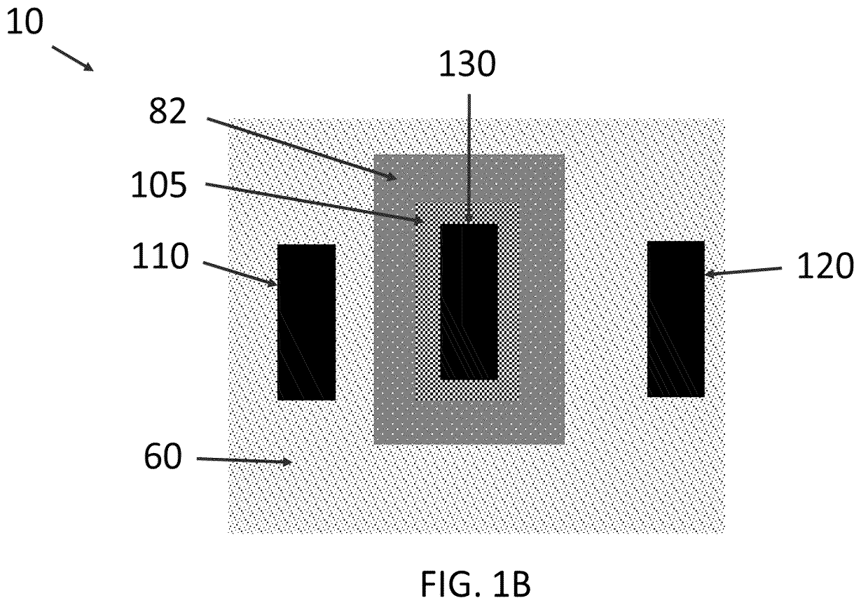

FIG. 1A shows a cross sectional view of a High-Electron-Mobility-Transistor according to one or more examples. As shown in FIG. 1A, the High-Electron-Mobility-Transistor 10 may include a substrate 20 with a first buffer layer 40 formed on the substrate 20. The substrate 20 may comprise gallium nitride, diamond, silicon carbide, sapphire, aluminum nitride or silicon. The first buffer layer 40 may comprise a III-V compound semiconductor such as gallium nitride. A first barrier layer 60 may be formed over the first buffer layer 40. The first barrier layer 60 may comprise aluminum gallium nitride. A doped structure 82 may be formed over a first portion 42 of the first barrier layer 60. The doped structure 82 may comprise P-doped gallium nitride. A first insulating layer 90 may be formed over a second portion 44 of the first barrier layer 60. The doped structure 82 may be surrounded by the first insulating layer 90. The first insulating layer 90 may comprise polysilicon, silicon dioxide or a mixture of polysilicon and silicon dioxide or any other insulating material or a mixture of all these. The first insulating layer 90 may comprise an insulator having a K value between 1 to 3.9. A second barrier layer 65 may be formed over the first insulating layer 90 and over a first portion 84 of the doped structure 82. The second barrier layer 65 may comprise aluminum gallium nitride. A second buffer layer 45 may be formed over the second barrier layer 65. The second buffer layer 45 may comprise a III-V compound semiconductor such as gallium nitride. A second insulating layer 100 may be formed over the second buffer layer 45. The second insulating layer 100 may comprise polysilicon, silicon dioxide or a mixture of polysilicon and silicon dioxide or any other insulating material or a mixture of all these. The second insulating layer 100 may comprise an insulator having a K value between 1 to 3.9. A spacer 105 may be formed over a second portion 86 of the doped structure 82 through the second insulating layer 100, through the second buffer layer 45 and through the second barrier layer 65. A gate electrode 130 may be formed within the spacer 105 through the second insulating layer 100, through the second buffer layer 45 and through the second barrier layer 65. The gate electrode 130 may be connected to the doped structure 82. A drain terminal 120 may be formed at a first side of the gate electrode 130. A source terminal 110 may be formed at a second side of the gate electrode 130.

FIG. 1B is a top sectional view of a High-Electron-Mobility-Transistor 10 according to one or more examples. As shown in the top view of FIG. 1B, the High-Electron-Mobility-Transistor 10 may include a barrier layer 60 that surrounds a doped structure 82. The barrier layer 60 may comprise aluminum gallium nitride. The doped structure 82 may surround a spacer 105. The doped structure 82 may comprise P-doped gallium nitride. The spacer 105 may surround a gate electrode 130. FIG. 1B shows a drain terminal 120 may be formed at a first side of the gate electrode 130 within the barrier layer 60. FIG. 1B shows a source terminal 110 may be formed at a second side of the gate electrode 130 within the barrier layer 60.

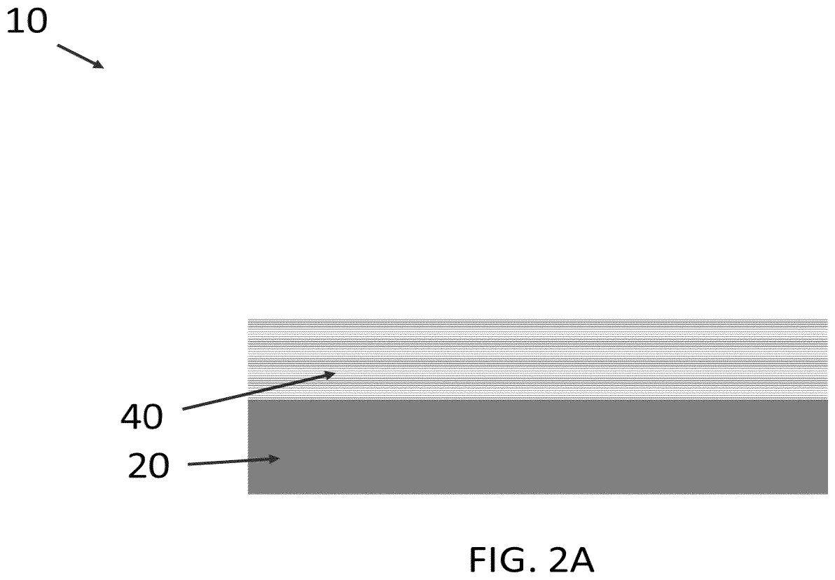

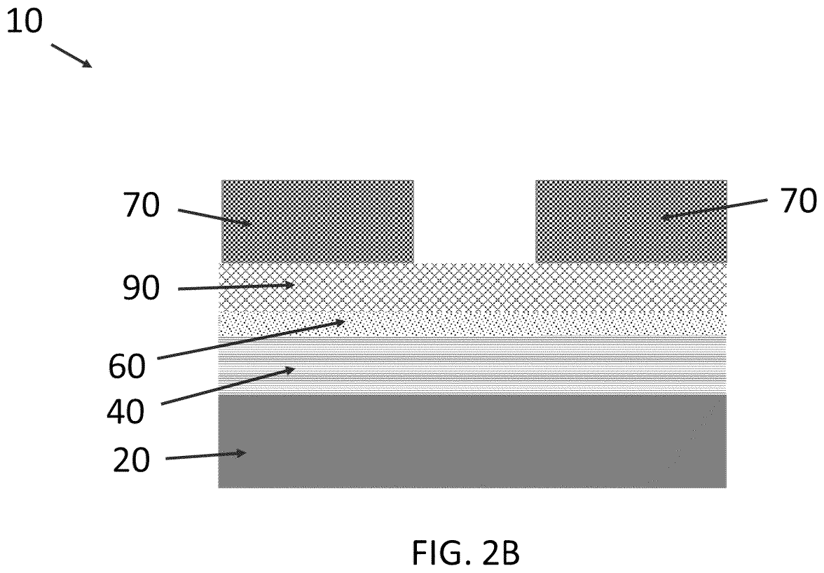

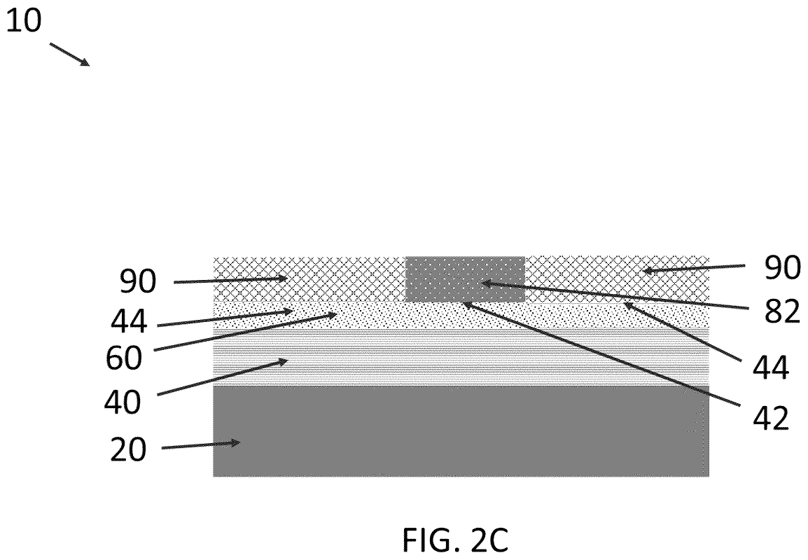

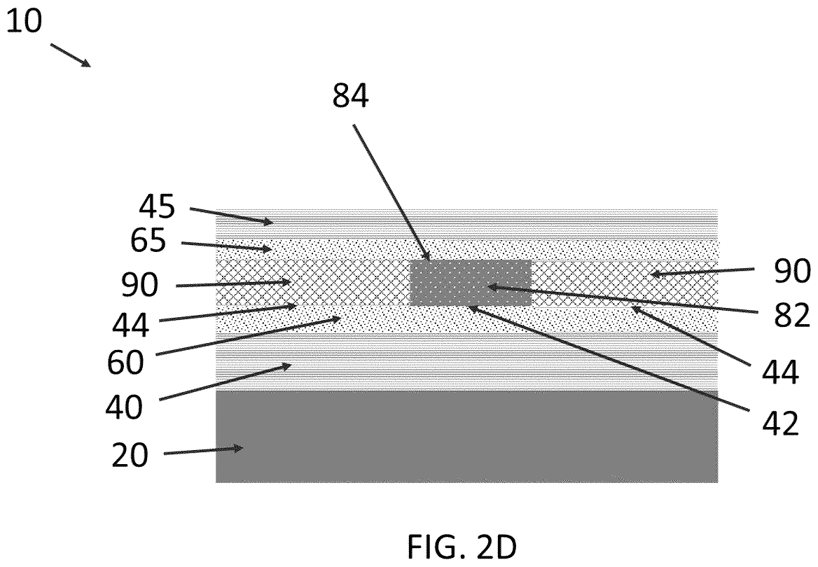

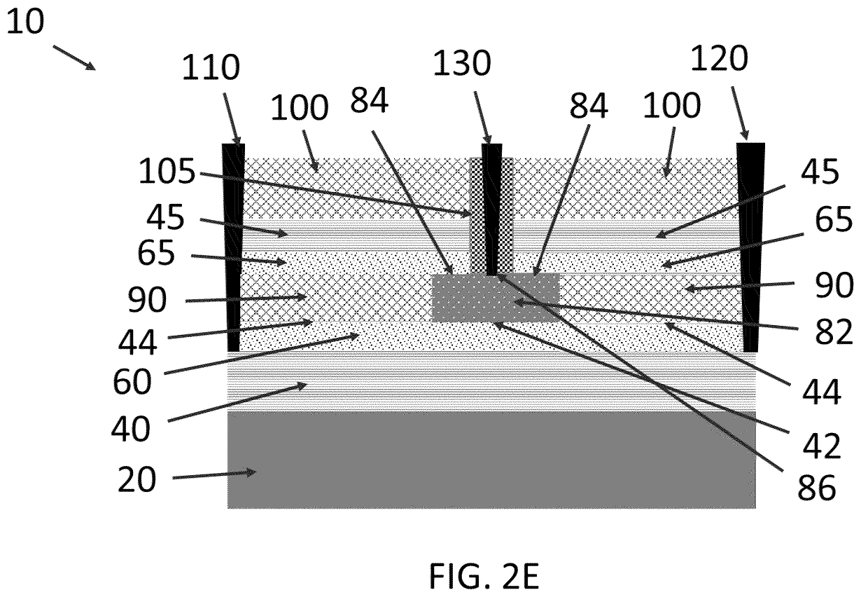

FIGS. 2A-2E show a method of manufacturing a High-Electron-Mobility-Transistor according to one or more examples. Although the example method shown in FIGS. 2A-2E includes steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A is a cross sectional view of some of the steps in a method of manufacturing a High-Electron-Mobility-Transistor 10 according to one or more examples. In FIG. 2A, the example method may include forming a first buffer layer 40 on a substrate 20. The first buffer layer 40 may comprise a III-V compound semiconductor such as gallium nitride. The substrate 20 may comprise gallium nitride, diamond, silicon carbide, sapphire, aluminum nitride or silicon.

FIG. 2B is cross sectional view of some of the steps in a method of manufacturing a High-Electron-Mobility-Transistor 10 according to one or more examples. In FIG. 2B, the example method may include forming a first barrier layer 60 over the first buffer layer 40. The first barrier layer 60 may comprise aluminum gallium nitride. In FIG. 2B, the example method may include forming a first insulating layer 90 over the first barrier layer 60. The first insulating layer 90 may comprise polysilicon, silicon dioxide or a mixture of polysilicon and silicon dioxide or any other insulating material or a mixture of all these. The first insulating layer 90 may comprise an insulator having a K value between 1 to 3.9. In FIG. 2B, the example method may include forming a gate mask 70 over the insulating layer 90.

FIG. 2C is cross sectional view of some of the steps in a method of manufacturing a High-Electron-Mobility-Transistor 10 according to one or more examples. In FIG. 2C, the example method may include forming the doped structure 82 over a first portion 42 of the first barrier layer 60 while leaving the first insulating layer 90 over a second portion 44 of the first barrier layer 60. The doped structure 82 may comprise P-doped gallium nitride.

FIG. 2D is cross sectional view of some of the steps in a method of manufacturing a High-Electron-Mobility-Transistor 10 according to one or more examples. In FIG. 2D, the example method may include forming a second barrier layer 65 over the first insulating layer 90 and over a first portion 84 of the doped structure 82. The second barrier layer 65 may comprise aluminum gallium nitride. In FIG. 2D, the example method may include forming a second buffer layer 45 over the second barrier layer 65. The second buffer layer 45 may comprise a III-V compound semiconductor such as gallium nitride.

FIG. 2E is cross sectional view of some of the steps in a method of manufacturing a High-Electron-Mobility-Transistor 10 according to one or more examples. In FIG. 2E, the example method may include forming a second insulating layer 100 over the second buffer layer 45. The second insulating layer 100 may comprise polysilicon, silicon dioxide or a mixture of polysilicon and silicon dioxide or any other insulating material or a mixture of all these. The second insulating layer 100 may comprise an insulator having a K value between 1 to 3.9. In FIG. 2E, the example method may include forming a spacer 105 over a second portion 86 of the doped structure 82 through the second insulating layer 100, through the second buffer layer 45 and through the second barrier layer 65. In FIG. 2E, the example method may include forming a gate electrode 130 within the spacer 105 through the second insulating layer 100, through the second buffer layer 45 and through the second barrier layer 65. The gate electrode 130 may be connected to the doped structure 82. In FIG. 2E, the example method may include forming a drain terminal 120 at a first side of the gate electrode 130. In FIG. 2E, the example method may include forming a source terminal 110 at a second side of the gate electrode 130.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A High-Electron-Mobility-Transistor comprising:
a substrate;
a first buffer layer formed on the substrate;
a first barrier layer formed over the first buffer layer;
a doped structure formed over a first portion of the first barrier layer;
a first insulating layer formed over a second portion of the first barrier layer and surrounding the doped structure;
a second barrier layer formed over the first insulating layer and formed over a first portion of the doped structure;
a second buffer layer formed over the second barrier layer;
a second insulating layer formed over the second buffer layer;
a spacer formed over a second portion of the doped structure through the second insulating layer, through the second buffer layer, and through the second barrier layer;
a gate electrode formed within the spacer through the second insulating layer, through the second buffer layer, and through the second barrier layer, the gate electrode connected to the doped structure;
a drain terminal formed at a first side of the gate electrode; and
a source terminal formed at a second side of the gate electrode.

2. The High-Electron-Mobility-Transistor of claim 1, wherein the substrate comprises gallium nitride, diamond, silicon carbide, sapphire, aluminum nitride, or silicon.

3. The High-Electron-Mobility-Transistor of claim 1, wherein the first buffer layer comprises a first III-V compound semiconductor.

4. The High-Electron-Mobility-Transistor of claim 3, wherein the second buffer layer comprises a second III-V compound semiconductor.

5. The High-Electron-Mobility-Transistor of claim 1, wherein the first buffer layer and the second buffer layer comprises gallium nitride.

6. The High-Electron-Mobility-Transistor of claim 1, wherein the first barrier layer comprises aluminum gallium nitride.

7. The High-Electron-Mobility-Transistor of claim 6, wherein the second barrier layer comprises aluminum gallium nitride.

8. The High-Electron-Mobility-Transistor of claim 1, wherein the doped structure comprises P-doped gallium nitride.

9. The High-Electron-Mobility-Transistor of claim 1, wherein the first insulating layer comprises polysilicon, silicon dioxide, or a mixture of polysilicon and silicon dioxide.

10. The High-Electron-Mobility-Transistor of claim 9, wherein the second insulating layer comprises polysilicon, silicon dioxide, or a mixture of polysilicon and silicon dioxide.

11. A method for producing a High-Electron-Mobility-Transistor comprising:
providing a substrate;
forming a first buffer layer on the substrate;
forming a first barrier layer over the first buffer layer;
forming a first insulating layer over a first portion of the first barrier layer;
forming a doped structure over a second portion of the first barrier layer and surrounded by the first insulating layer;
forming a second barrier layer over the first insulating layer and over a portion of the doped structure;
forming a second buffer layer over the second barrier layer;
forming a second insulating layer over the second buffer layer;
forming a spacer over the portion of the doped structure, the spacer going through the second insulating layer, through the second buffer layer, and through the second barrier layer;
forming a gate electrode within the spacer through the second insulating layer, through the second buffer layer, and through the second barrier layer, the gate electrode connected to the doped structure;
forming a drain terminal at a first side of the gate electrode; and
forming a source terminal at a second side of the gate electrode.

12. The method for producing a High-Electron-Mobility-Transistor of claim 11, wherein the substrate comprises gallium nitride, diamond, silicon carbide, sapphire, aluminum nitride, or silicon.

13. The method for producing a High-Electron-Mobility-Transistor of claim 11, wherein the first buffer layer comprises a first III-V compound semiconductor.

14. The method for producing a High-Electron-Mobility-Transistor of claim 13, wherein the second buffer layer comprises a second III-V compound semiconductor.

15. The method for producing a High-Electron-Mobility-Transistor of claim 11, wherein the first buffer layer and the second buffer layer comprises gallium nitride.

16. The method for producing a High-Electron-Mobility-Transistor of claim 11, wherein the first barrier layer comprises aluminum gallium nitride.

17. The method for producing a High-Electron-Mobility-Transistor of claim 16, wherein the second barrier layer comprises aluminum gallium nitride.

18. The method for producing a High-Electron-Mobility-Transistor of claim 11, wherein the doped structure comprises P-doped gallium nitride.

19. The method for producing a High-Electron-Mobility-Transistor of claim 11, wherein the first insulating layer comprises polysilicon, silicon dioxide, or a mixture of polysilicon and silicon dioxide.

20. The method for producing a High-Electron-Mobility-Transistor of claim 19, wherein the second insulating layer comprises polysilicon, silicon dioxide, or a mixture of polysilicon and silicon dioxide.
